(19) United States
(12) Patent Application Publication
(10) Pub. No.: US 2025/0212501 A1
(43) Pub. Date: Jun. 26, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kei TANIHIRA, Himeji Hyogo (JP); Masaru FURUKAWA, Himeji Hyogo (JP)

(21) Appl. No.: 19/079,300

(22) Filed: Mar. 13, 2025

Related U.S. Application Data
(63) Continuation of application No. PCT/JP2024/007044, filed on Feb. 27, 2024.

(30) Foreign Application Priority Data
Jul. 13, 2023 (JP) 2023-115493

(51) Int. Cl. H10D 84/00; H10D 8/50; H10D 8/60

(52) U.S. Cl. CPC H10D 84/221; H10D 8/50; H10D 8/60

(57) ABSTRACT

A semiconductor device according to one embodiment includes a first electrode, a second electrode, a semiconductor layer between the first electrode and the second electrode, a plurality of first semiconductor regions on a side of the first electrode, a plurality of second semiconductor regions on surface sides of the plurality of first semiconductor regions, and a plurality of PIN diode regions provided on the side of the first electrode in the semiconductor layer, the plurality of PIN diode regions extending in a third direction orthogonal to the first direction and the second direction, the plurality of PIN diode regions electrically connected to at least one of the plurality of first semiconductor regions and at least one of the plurality of second semiconductor regions.

### CROSS-REFERENCE TO RELATED APPLICATIONS

This application is based upon and claims the benefit of priority from Japanese Patent Application No. 2023-115493, filed on Jul. 13, 2023 and PCT Application No. PCT/JP2024/007044, filed on Feb. 27, 2024; the entire contents of which are incorporated herein by reference.

### FIELD

Embodiments of the present invention relate to semiconductor devices.

### BACKGROUND

In a JBS (Junction Barrier Schottky Diode) that is one of an SBD (Schottky Barrier Diode), a plurality of p-type semiconductor regions is formed in stripes. Further, in the JBS, PIN diode regions are dispersedly arranged inside the n-type semiconductor region. In the PIN diode region, a metal silicide layer is formed between an anode electrode and the p-type semiconductor region to reduce the contact resistance. The PIN diode region can cause a large forward surge current to flow through the inside of the n-type semiconductor region, using conductivity modulation.

### BRIEF DESCRIPTION OF THE DRAWINGS

FIG. 1 is a plan view of a semiconductor device according to a first embodiment;

FIG. 2 is a cross-sectional view taken along cut-line A-A shown in FIG. 1;

FIG. 3 is a cross-sectional view for explaining a forming process for a p-type semiconductor region;

FIG. 4 is a cross-sectional view for explaining a forming process for a p⁺-type semiconductor region;

FIG. 5 is a cross-sectional view for explaining a forming process for a metal silicide layer;

FIG. 6 is a plan view of a semiconductor device according to Comparative Example;

FIG. 7 is a cross-sectional view taken along cut-line B-B shown in FIG. 6;

FIG. 8 is a plan view of a semiconductor device according to a second embodiment;

FIG. 9 is a cross-sectional view taken along cut-line C-C shown in FIG. 8;

FIG. 10 is a plan view of a semiconductor device according to a third embodiment;

FIG. 11 is a cross-sectional view taken along cut-line D-D shown in FIG. 10;

FIG. 12 is a plan view of a semiconductor device according to a fourth embodiment; and

FIG. 13 is a cross-sectional view taken along cut-line E-E shown in FIG. 12.

### DETAILED DESCRIPTION

Embodiments will now be explained with reference to the accompanying drawings. The present invention is not limited to the embodiments.

A semiconductor device according to one embodiment includes a first electrode, a second electrode opposing the first electrode in a first direction, a semiconductor layer of a first conductive type provided between the first electrode and the second electrode, a plurality of first semiconductor regions of a second conductive type provided on a side of the first electrode in the semiconductor layer, the plurality of first semiconductor regions extending in a second direction orthogonal to the first direction, a plurality of second semiconductor regions provided on surface sides of the plurality of first semiconductor regions, the plurality of second semiconductor regions having a concentration of an impurity of the second conductive type that is higher as compared to the first semiconductor region, and a plurality of PIN diode regions provided on the side of the first electrode in the semiconductor layer, the plurality of PIN diode regions extending in a third direction orthogonal to the first direction and the second direction, the plurality of PIN diode regions electrically connected to at least one of the plurality of first semiconductor regions and at least one of the plurality of second semiconductor regions.

### First Embodiment

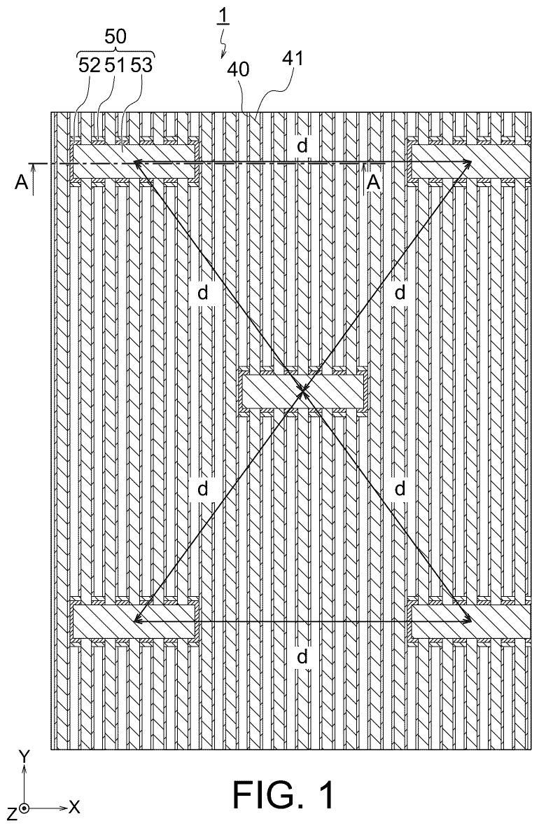

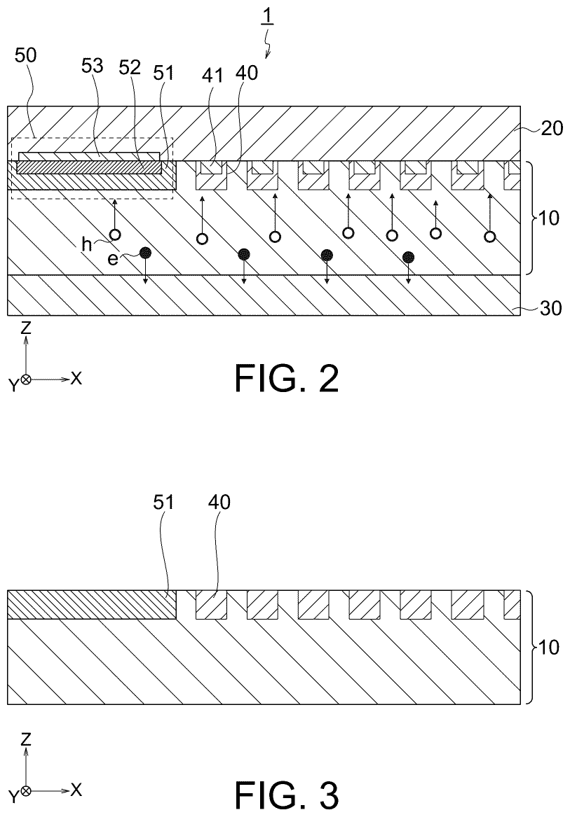

FIG. 1 is a plan view of a semiconductor device according to a first embodiment. FIG. 2 is a cross-sectional view taken along cut-line A-A shown in FIG. 1. A semiconductor device 1 according to the present embodiment is an SBD, more specifically, a JBS. The semiconductor device 1 includes an n-type semiconductor layer 10, an anode electrode 20, and a cathode electrode 30. The n-type semiconductor layer 10, the anode electrode 20, and the cathode electrode 30 correspond to a semiconductor layer of a first conductive type, a first electrode, and a second electrode, respectively.

In some descriptions below, the arrangement and the structure of each part of the semiconductor device are described using an X-axis, a Y-axis, and a Z-axis shown in each drawing. The X-axis, the Y-axis, and the Z-axis are orthogonal to each other and represent an X-direction (third direction), a Y-direction (second direction), and a Z-direction (first direction), respectively. Further, some descriptions will be made referring to the Z-direction as an upper side and the opposite direction as a lower side. In the present embodiment, the X-direction and the Y-direction represent in-plane directions parallel to the semiconductor device 1, and the Z-direction represents an out-of-plane direction orthogonal to the semiconductor device 1. Further, notation of p, pp⁺ means that the p-type impurity concentration increases in this order.

An impurity concentration can be measured by, for example, an SIMS (Secondary Ion Mass Spectrometry). Further, a relative level in the impurity concentration can also be determined, for example, based on the level in a carrier concentration obtained by a SCM (Scanning Capacitance Microscopy). Furthermore, a distance such as a depth of the semiconductor region can be obtained by, for example, the SIMS.

The n-type semiconductor layer 10 is provided between the anode electrode 20 and the cathode electrode 30. The n-type semiconductor layer 10 is composed of, for example, epitaxially grown SiC (silicon carbide). On a surface side of the n-type semiconductor layer 10 contacting the anode electrode 20, a plurality of p-type semiconductor regions 40 and a plurality of PIN diode regions 50 are provided as shown in FIG. 2.

Each p-type semiconductor region 40 corresponds to a first semiconductor region. On a surface side of each p-type semiconductor region 40, a p⁺-type semiconductor region 41 is provided. The p⁺-type semiconductor region 41 corresponds to a second semiconductor region having a p-type impurity concentration higher than that of the p-type semiconductor region 40.

The p-type semiconductor region 40 and the p⁺-type semiconductor region 41 are formed in a stripe form extending in the Y-direction as shown in FIG. 1.

Each PIN diode region 50 extends in the X-direction on the surface side of the n-type semiconductor layer 10 as shown in FIG. 1. A plane figure of each PIN diode region 50 is a rectangle having the length in the X-direction longer than the length in the Y-direction. Further, each PIN diode region 50 is electrically connected to at least one of the plurality of p-type semiconductor regions 40 and at least one of the plurality of p⁺-type semiconductor regions 41.

Further, the plurality of PIN diode regions 50 is evenly arranged so that center distances d are equal to each other as shown in FIG. 1. For example, two PIN diode regions 50 spaced apart from each other in the X-direction and one PIN diode region 50 displaced in the Y-direction relative to the two PIN diode regions 50 are arranged so as to form a regular triangle.

Each PIN diode region 50 includes a p-type semiconductor region 51, a p⁺-type semiconductor region 52, and a metal silicide layer 53. The p-type semiconductor region 51 corresponds to a third semiconductor region having the same p-type impurity concentration as that of the p-type semiconductor region 40. The p⁺-type semiconductor region 52 corresponds to a fourth semiconductor region having the p-type impurity concentration higher than that of the p-type semiconductor region 51 and the same p-type impurity concentration as that of the p⁺-type semiconductor region 41.

Each p-type semiconductor region 51 has the same thickness as that of the p-type semiconductor region 40. Further, each p-type semiconductor region 51 contacts at least one of the plurality of p-type semiconductor regions 40 within the PIN diode region 50.

Each p⁺-type semiconductor region 52 is provided on a surface side of the p-type semiconductor region 51. Further, each p⁺-type semiconductor region 52 has the same thickness as that of the p⁺-type semiconductor region 41. Further, each p⁺-type semiconductor region 52 contacts at least one of the plurality of p⁺-type semiconductor region 41 within the PIN diode region 50.

Each metal silicide layer 53 is provided between the p⁺-type semiconductor region 52 and the anode electrode 20. With the metal silicide layer 53, the contact between the pp⁺-type semiconductor region 52 and the anode electrode 20 is an ohmic contact.

As shown in FIG. 2, the anode electrode 20 contacts the n-type semiconductor layer 10, the p-type semiconductor region 40, the pp⁺-type semiconductor region 41, the p-type semiconductor region 51, and the metal silicide layer 53. The anode electrode 20 is composed of a metal layer. The metal layer structure may be a single layer structure or a stacked layer structure in which, for example, titanium and aluminum are stacked. The anode electrode 20 opposes the cathode electrode 30 across the n-type semiconductor layer 10 in the Z-direction.

The cathode electrode 30 contacts a back surface (bottom surface) of the n-type semiconductor layer 10. The cathode electrode 30 is composed of a metal layer. The metal layer structure may be a single layer structure composed of nickel silicide, titanium, nickel, silver, gold, or the like or a stacked layer structure in which any of a plurality of materials selected from the group of these metals are stacked.

Next, with reference to FIG. 2 to FIG. 5, an example of a manufacturing method for the semiconductor device 1 configured as described above will be described.

First, as shown in FIG. 3, the p-type semiconductor region 40 and the p-type semiconductor region 51 are simultaneously formed on the surface side of the n-type semiconductor layer 10. The p-type semiconductor region 40 and the p-type semiconductor region 51 can be formed by ion implantation of a p-type impurity into the surface of the n-type semiconductor layer 10, for example, using a mask having an opening in a portion for forming each p-type semiconductor region. At this time, the p-type impurity is, for example, aluminum. In this case, the p-type impurity concentration is around 1×10¹⁶ cm⁻³. Further, the material of the mask is, for example, an oxide film or a resist.

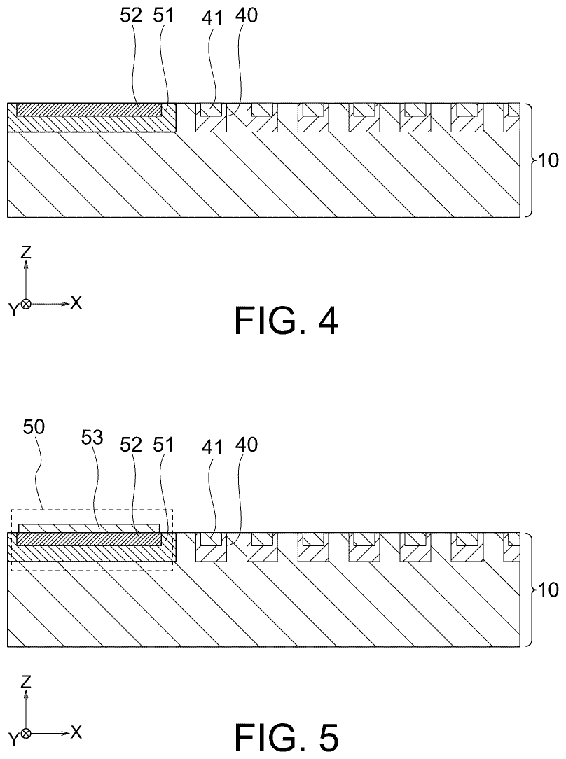

Next, as shown in FIG. 4, the p⁺-type semiconductor region 41 is formed on a surface of the p-type semiconductor region 40 and simultaneously, the p⁺-type semiconductor region 52 is formed on a surface of the p-type semiconductor region 51. In the same manner as in the p-type semiconductor regions 40, 51, the p⁺-type semiconductor regions 41, 52 can also be formed by ion implantation of a p-type impurity into the surface of each p-type semiconductor region using a mask having an opening in a portion for forming each p⁺-type semiconductor region. However, the concentration of aluminum to be implanted at this time is higher as compared to when the p-type semiconductor regions 40, 51 are formed and is, for example, around 1×10²⁰ cm⁻³.

Next, as shown in FIG. 5, the metal silicide layer 53 is formed on a surface of the p⁺-type semiconductor region 52. Thus, the PIN diode region 50 is completed. In forming the metal silicide layer 53, first, a silicon film is formed on the surface of the p⁺-type semiconductor region 52. Subsequently, a metal film composed of nickel (Ni), titanium (Ti), or the like is formed by, for example, sputtering. Thereafter, silicon and metal are reacted with each other through annealing or the like to form the metal silicide layer 53.

Finally, referring back to FIG. 2, the anode electrode 20 and the cathode electrode 30 are formed on opposite sides of the n-type semiconductor layer 10, so that the semiconductor device 1 according to the present embodiment is completed. Note that the aforementioned manufacturing process is an example of the manufacturing method for the semiconductor device 1 according to the first embodiment, and does not limit the manufacturing method.

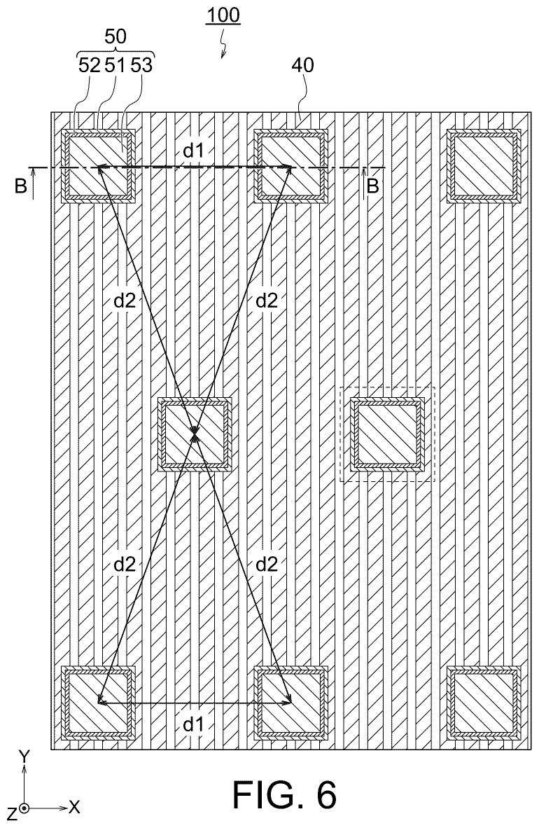

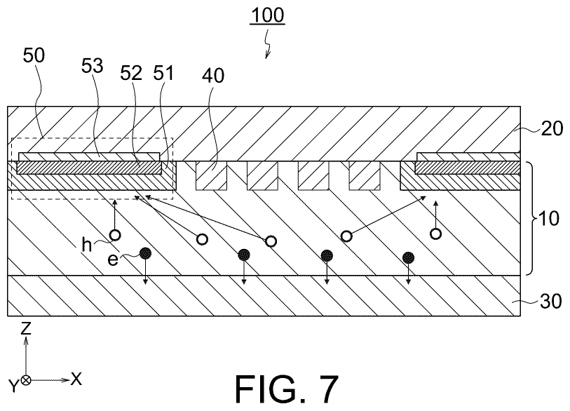

Here, with reference to FIG. 6 and FIG. 7, Comparative Example to be compared with the present embodiment will be described.

FIG. 6 is a plan view of a semiconductor device according to Comparative Example. FIG. 7 is a cross-sectional view taken along cut-line B-B shown in FIG. 6. In FIG. 6 and FIG. 7, for the same constituent elements as those of the aforementioned semiconductor device 1, the same reference signs are assigned and the detailed descriptions will be omitted.

In a semiconductor device 100 according to the present comparative example, the plurality of PIN diode regions 50 are not equally arranged as shown in FIG. 6. For example, three PIN diode regions 50 are arranged such that the center of each PIN diode region 50 is an apex of an isosceles triangle. In this case, a center distance d1 between the two PIN diode regions 50 spaced apart from each other in the X-direction, that is, the length of the base of the isosceles triangle differs from a center distance d2 between the PIN diode regions 50, which corresponds to the length of the hypotenuse of the aforementioned isosceles triangle.

In the semiconductor device 100 configured as described above, when voltage is applied by having the anode electrode 20 with a low potential and the cathode electrode 30 with a high potential, electrons e within the n-type semiconductor layer 10 move toward the cathode electrode 30.

Meanwhile, holes h within the n-type semiconductor layer 10 move toward the PIN diode regions 50. At this time, in the semiconductor device 100, the PIN diode regions 50 are not equally arranged. Therefore, for some holes h, the distance to the PIN diode region 50 becomes longer. As a result, thermal destruction of the semiconductor device 100 due to the heat generated in accordance with the movement of the holes h is concerned.

By contrast, in the semiconductor device 1 according to the present embodiment, the p⁺-type semiconductor region 41 is provided on the surface of the p-type semiconductor region 40, as shown in FIG. 2. Further, the PIN diode regions 50 are equally arranged. Therefore, when voltage is applied between the anode electrode 20 and the cathode electrode 30, the holes h far from the PIN diode region 50 move toward the p-type semiconductor region 40, as shown in FIG. 2. As a result, the moving distance of the holes h is reduced as compared to Comparative Example and thus, the heat is less likely to be generated.

Thus, according to the present embodiment, the risk of thermal destruction can be reduced.

### Second embodiment

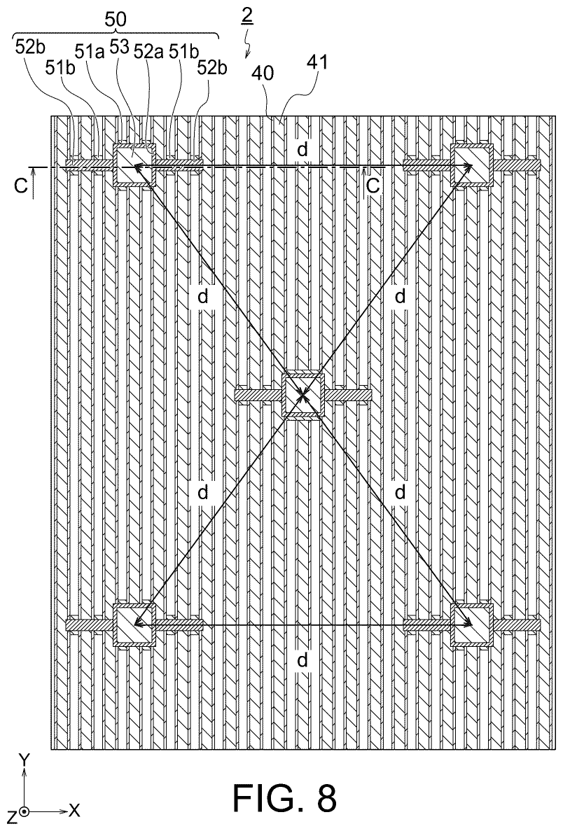

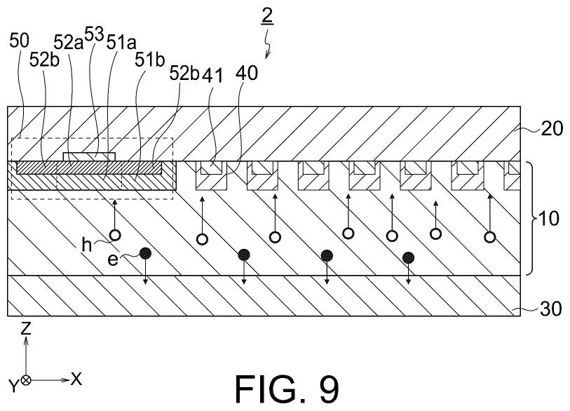

FIG. 8 is a plan view of a semiconductor device according to a second embodiment. FIG. 9 is a cross-sectional view taken along cut-line C-C shown in FIG. 8. In FIG. 8 and FIG. 9, for the same constituent elements as those of the aforementioned first embodiment, the same reference signs are assigned and the detailed descriptions will be omitted.

In a semiconductor device 2 according to the present embodiment, the PIN diode regions 50 are equally arranged in the same manner as in the first embodiment, as shown in FIG. 8. That is, three PIN diode regions 50 are arranged so as to form a regular triangle.

Meanwhile, in the present embodiment, the shape of the PIN diode region 50 differs from that of the first embodiment. Specifically, the p-type semiconductor region 51 includes a first area 51a and a second area 51b. The first area 51a is a region opposing the metal silicide layer 53 in the Z-direction. Further, the second area 51b is a cross-linked region extending in the X-direction from an outer periphery portion of the first area 51a. The length (longitudinal width) in the Y-direction of the second area 51b is shorter than the length (longitudinal width) in the Y-direction of the first area 51a.

Further, in the present embodiment, the p⁺-type semiconductor region 52 includes a first area 52a and a second area 52b. The first area 52a is a region provided between the first area 51a and the metal silicide layer 53. Furthermore, the second area 52b is a cross-linked region extending in the X-direction from an outer periphery portion of the first area 52a on the second area 51b. The length (longitudinal width) in the Y-direction of the second area 52b is shorter than the length (longitudinal width) in the Y-direction of the first area 52a.

Moreover, in the present embodiment, the length (lateral width) in the X-direction of the metal silicide layer 53 is shorter as compared to the first embodiment. In the first embodiment, as shown in FIG. 1, the length (lateral width) in the X-direction of the metal silicide layer 53 is longer than the length (longitudinal width) in the Y-direction so that all the p⁺-type semiconductor regions 41 are electrically connected to at least one metal silicide layer 53 via the p⁺-type semiconductor region 52.

Meanwhile, in the present embodiment, as shown in FIG. 8, a part of the plurality of p⁺-type semiconductor regions 41 is electrically connected to at least one metal silicide layer 53 via the first area 52a, and the remainder of the plurality of p⁺-type semiconductor regions 41 is electrically connected to at least one metal silicide layer 53 via the second area 52b and the first area 52a. Therefore, the lateral width of the metal silicide layer 53 is shorter.

The semiconductor device 2 according to the present embodiment can be manufactured through the same process as in the semiconductor device 1 according to the aforementioned first embodiment. However, in forming the p-type semiconductor region 51, p-type impurity (for example, aluminum) ions are implanted using a mask following, in shape, the first area 51a and the second area 51b. Further, in forming the p⁺-type semiconductor region 52, p-type impurity (for example, aluminum) ions are implanted using a mask following, in shape, the first area 52a and the second area 52b.

According to the present embodiment, the p⁺-type semiconductor region 41 is provided on the surface of the p-type semiconductor region 40 in the same manner as in the first embodiment. Further, the PIN diode regions 50 are equally arranged. Therefore, when voltage is applied between the anode electrode 20 and the cathode electrode 30, the holes h far from the PIN diode region 50 move toward the p-type semiconductor region 40, as shown in FIG. 9. As a result, the moving distance of the holes h is reduced and thus, the heat is less likely to be generated. Accordingly, the risk of thermal destruction can be reduced.

Moreover, in the present embodiment, the lateral width of the metal silicide layer 53 is shorter as compared to the first embodiment. Therefore, the area of the metal silicide layer 53 is reduced as compared to the first embodiment, so that the effective area functioning as the SBD increases. As a result, it is possible to improve the characteristics of the forward voltage.

### Third Embodiment

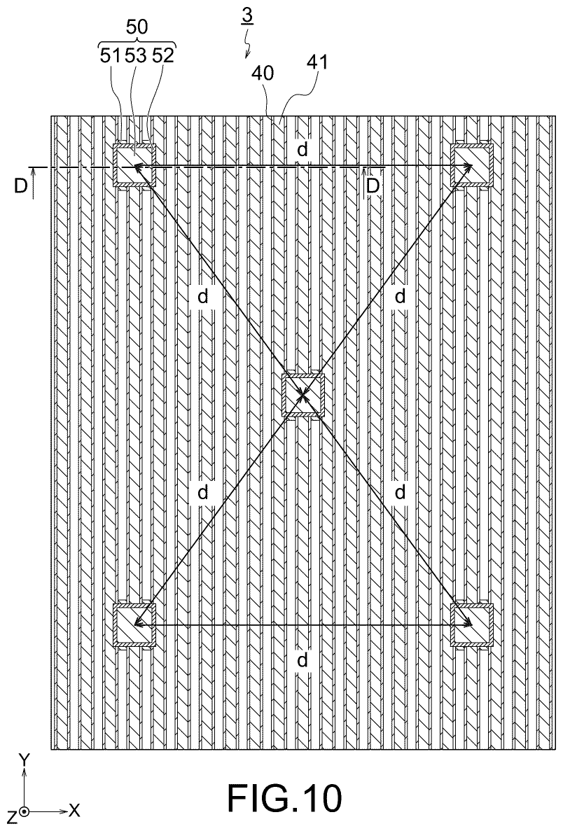

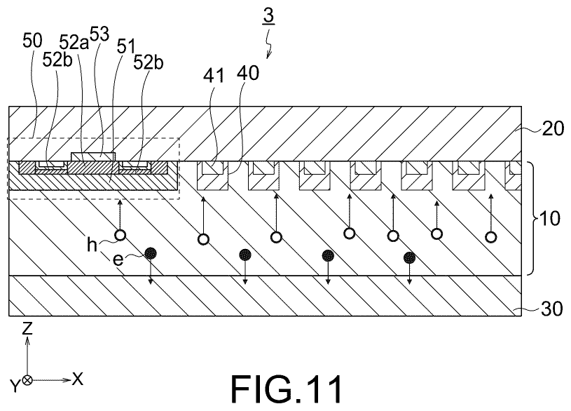

FIG. 10 is a plan view of a semiconductor device according to a third embodiment. FIG. 11 is a cross-sectional view taken along cut-line D-D shown in FIG. 10. In FIG. 10 and FIG. 11, for the same constituent elements as those of the aforementioned first embodiment and second embodiment, the same reference signs are assigned and the detailed descriptions will be omitted.

In a semiconductor device 3 according to the present embodiment, the PIN diode regions 50 are equally arranged in the same manner as in the second embodiment, as shown in FIG. 10. That is, three PIN diode regions 50 are arranged so as to form a regular triangle.

Further, in the semiconductor device 3 according to the present embodiment, the p⁺-type semiconductor region 52 of the PIN diode region 50 includes the first area 52a and the second area 52b as with the second embodiment. The first area 52a is a region provided between the p-type semiconductor region 51 and the metal silicide layer 53.

Furthermore, in the semiconductor device 3 according to the present embodiment, the length (lateral width) in the X-direction of the metal silicide layer 53 is shorter as with the second embodiment.

Meanwhile, in the semiconductor device 3 according to the present embodiment, the second area 52b is provided inside the n-type semiconductor layer 10, as shown in FIG. 11. Therefore, with the second area 52b, the first area 52a and the p⁺-type semiconductor region 41 are electrically connected in the respective lower portions on side surfaces. Further, with the second area 52b provided inside the n-type semiconductor layer 10, the n-type semiconductor layer 10 is interposed between the second area 52b and the anode electrode 20.

The semiconductor device 3 according to the present embodiment can be manufactured through the same process as in the semiconductor device 1 according to the aforementioned first embodiment. However, in forming the p⁺-type semiconductor region 52, p-type impurity (for example, aluminum) ions are implanted using different masks and at different timings for the first area 52a and the second area 52b. In forming the first area 52a, the p-type impurity ions are implanted into the surface of the n-type semiconductor layer 10 (p-type semiconductor region 51). Meanwhile, in forming the second area 52b, the p-type impurity ions are implanted inside the n-type semiconductor layer 10.

According to the present embodiment, the p⁺-type semiconductor region 41 is provided on the surface of the p-type semiconductor region 40 in the same manner as in the second embodiment. Further, the PIN diode regions 50 are equally arranged. Therefore, when voltage is applied between the anode electrode 20 and the cathode electrode 30, the holes h far from the PIN diode region 50 move toward the p-type semiconductor region 40, as shown in FIG. 11. As a result, the moving distance of the holes h is reduced and thus, the heat is less likely to be generated. Accordingly, the risk of thermal destruction can be reduced.

Further, in the present embodiment, since the second area 52b of the p⁺-type semiconductor region 52 is provided inside the n-type semiconductor layer 10, the n-type semiconductor layer 10 is interposed between the second area 52b and the anode electrode 20. Therefore, the area of the n-type semiconductor layer 10 is reduced as compared to the second embodiment, so that the effective area functioning as the SBD increases. As a result, it is possible to further improve the characteristics of the forward voltage.

### Fourth Embodiment

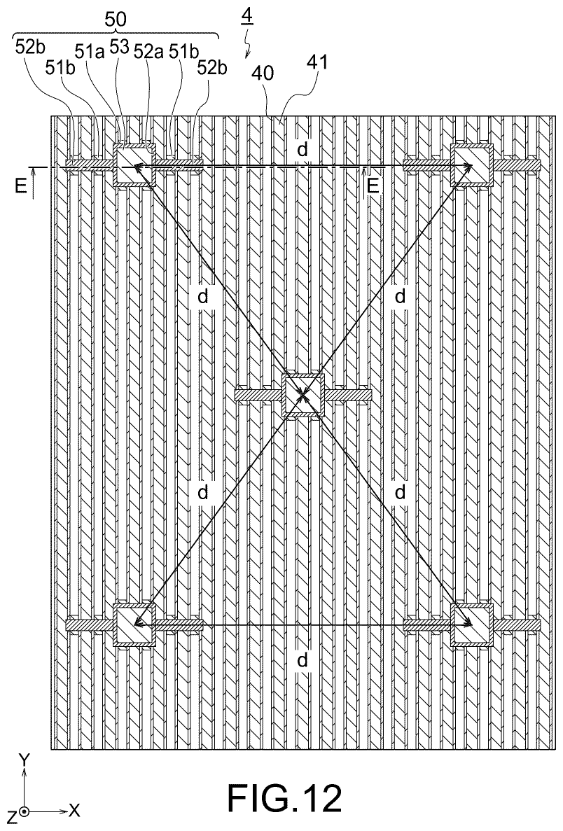

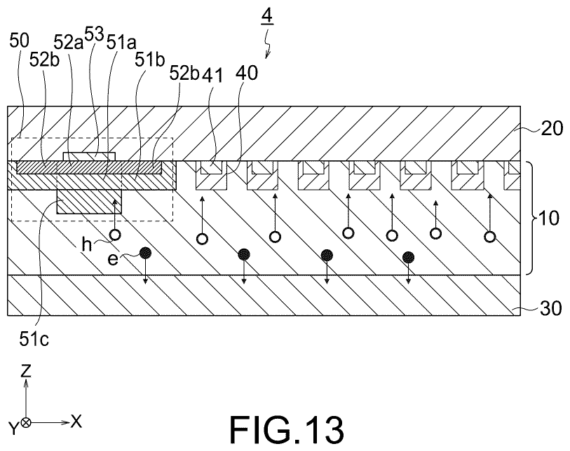

FIG. 12 is a plan view of a semiconductor device according to a fourth embodiment. FIG. 13 is a cross-sectional view taken along cut- line E-E shown in FIG. 12. In FIG. 12 and FIG. 13, for the same constituent elements as those of the aforementioned first embodiment and second embodiment, the same reference signs are assigned and the detailed descriptions will be omitted.

In a semiconductor device 4 according to the present embodiment, the PIN diode regions 50 are equally arranged in the same manner as in the second embodiment, as shown in FIG. 12. That is, three PIN diode regions 50 are arranged so as to form a regular triangle.

Further, in the semiconductor device 4 according to the present embodiment, the p⁺-type semiconductor region 52 includes the first area 52a and the second area 52b as with the second embodiment. Furthermore, the length (lateral width) in the X-direction of the metal silicide layer 53 is shorter.

Meanwhile, in the semiconductor device 4 according to the present embodiment, the p-type semiconductor region 51 further includes a third area 51c in addition to the first area 51a and the second area 51b. The third area 51c is an area that is immediately below the metal silicide layer 53 and that projects from a bottom surface of the first area 51a toward the cathode electrode 30.

The semiconductor device 4 according to the present embodiment can be manufactured through the same process as in the semiconductor device 1 according to the aforementioned first embodiment. However, in forming the p-type semiconductor region 51, in order to form the third area 51c, p-type impurity ions are implanted up to a position deeper than the first area 51a from the surface of the n-type semiconductor layer 10.

According to the present embodiment, the p⁺-type semiconductor region 41 is provided on the surface of the p-type semiconductor region 40 in the same manner as in the second embodiment. Further, the PIN diode regions 50 are equally arranged. Therefore, when voltage is applied between the anode electrode 20 and the cathode electrode 30, the holes h far from the PIN diode region 50 move toward the p-type semiconductor region 40, as shown in FIG. 13. As a result, the moving distance of the holes h is reduced and thus, the heat is less likely to be generated. Accordingly, the risk of thermal destruction can be reduced.

Further, in the present embodiment, the third area 51c is provided at a deep position immediately below the metal silicide layer 53 in the PIN diode region 50. Therefore, since the electric field is concentrated in the third area 51c, voltage breakdown is locally enabled immediately below the metal silicide layer 53. As a result, the holes h can be efficiently discharged from the n-type semiconductor layer 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a second electrode opposing the first electrode in a first direction;
a semiconductor layer of a first conductive type provided between the first electrode and the second electrode;
a plurality of first semiconductor regions of a second conductive type provided on a side of the first electrode in the semiconductor layer, the plurality of first semiconductor regions extending in a second direction orthogonal to the first direction;
a plurality of second semiconductor regions provided on surface sides of the plurality of first semiconductor regions, the plurality of second semiconductor regions having a concentration of an impurity of the second conductive type that is higher as compared to the first semiconductor region; and
a plurality of PIN diode regions provided on the side of the first electrode in the semiconductor layer, the plurality of PIN diode regions extending in a third direction orthogonal to the first direction and the second direction, the plurality of PIN diode regions electrically connected to at least one of the plurality of first semiconductor regions and at least one of the plurality of second semiconductor regions.

2. The semiconductor device according to claim 1, wherein the plurality of PIN diode regions each comprise:
a third semiconductor region of the second conductive type contacting at least one of the plurality of first semiconductor regions;
a fourth semiconductor region provided on a surface side of the third semiconductor region, the fourth semiconductor region having the concentration of the impurity of the second conductive type that is higher as compared to the third semiconductor region; and
a metal silicide layer provided between the fourth semiconductor region and the first electrode.

3. The semiconductor device according to claim 1, wherein the plurality of PIN diode regions is evenly arranged so that center distances are equal to each other.

4. The semiconductor device according to claim 3, wherein three of the plurality of PIN diode regions are arranged so as to form a regular triangle.

5. The semiconductor device according to claim 1, wherein a plane figure of each of the plurality of PIN diode regions is a rectangle having a length in the third direction longer than a length in the second direction.

6. The semiconductor device according to claim 2, wherein the fourth semiconductor region comprises:
a first area provided between the metal silicide layer and the third semiconductor region; and
a second area extending in the third direction from an outer periphery portion of the first area.

7. The semiconductor device according to claim 6, wherein
a part of the plurality of second semiconductor regions is electrically connected to the metal silicide layer via the first area, and
a remainder, excluding the part, of the plurality of second semiconductor regions is electrically connected to the metal silicide layer via the second area and the first area.

8. The semiconductor device according to claim 6, wherein the second area is provided inside the semiconductor layer.

9. The semiconductor device according to claim 2, wherein the third semiconductor region comprises an area that is immediately below the metal silicide layer and that projects toward the second electrode.

10. The semiconductor device according to claim 1, wherein the semiconductor device is a Schottky Barrier Diode.

11. The semiconductor device according to claim 2, wherein the plurality of PIN diode regions is evenly arranged so that center distances are equal to each other.

12. The semiconductor device according to claim 11, wherein three of the plurality of PIN diode regions are arranged so as to form a regular triangle

13. The semiconductor device according to claim 2, wherein a plane figure of each of the plurality of PIN diode regions is a rectangle having a length in the third direction longer than a length in the second direction.

14. The semiconductor device according to claim 2, wherein the semiconductor device is the Schottky Barrier Diode.

15. The semiconductor device according to claim 2, wherein a thickness of the third semiconductor region is same as a thickness of the first semiconductor region.

16. The semiconductor device according to claim 2, wherein the concentration of the impurity of the second conductive type of the third semiconductor region is same as the concentration of the impurity of the second conductive type of the first semiconductor region.

17. The semiconductor device according to claim 2, wherein a thickness of the fourth semiconductor region is same as a thickness of the second semiconductor region.

18. The semiconductor device according to claim 2, wherein the concentration of the impurity of the second conductive type of the fourth semiconductor region is same as the concentration of the impurity of the second conductive type of the second semiconductor region.

19. The semiconductor device according to claim 6, wherein a length in the second direction of the second area is shorter than a length in the second direction of the first area.

20. The semiconductor device according to claim 1, wherein the first conductive type is an n-type and the second conductive type is a p-type.
